(19) United States
(12) Patent Application Publication
(10) Pub. No.: US 2017/0162738 A9
(43) Pub. Date: Jun. 8, 2017

(54) METALLIC PHOTOVOLTAICS

(71) Applicant: Massachusetts Institute of Technology, Cambridge, MA (US)

(72) Inventors: Jesse H Mills, Fitchburg, MA (US); Jeremy S. Coombs, Foxboro, MA (US); Joshua L. Wilson, Harvest, AL (US); Mark A. Hollis, Concord, MA (US); Franz Busse, Acton, MA (US); Kenneth Alexander Diest, Bedford, MA (US)

(73) Assignee: Massachusetts Institute of Technology, Cambridge, MA (US)

(21) Appl. No.: 14/550,167

(22) Filed: Nov. 21, 2014

Related U.S. Application Data
(60) Provisional application No. 61/907,892, filed on Nov. 22, 2013.

(51) Int. Cl. H01L 31/07; H01L 31/18; H01L 31/054

(52) U.S. Cl. CPC H01L 31/07; H01L 31/0547; H01L 31/18

(57) ABSTRACT

According to some aspects, an apparatus for converting electromagnetic radiation into electric power is provided, comprising a first layer comprising a first semiconductor material, an absorber in contact with the first layer, a second layer comprising a second semiconductor material, the second layer being in contact with the absorber, and a reflector to reflect at least a portion of electromagnetic radiation passing through the second layer. According to some aspects, a method of forming an apparatus for converting electromagnetic radiation into electric power is provided, comprising forming a reflector on a substrate, forming a first layer in contact with the reflector, the first layer comprising a first semiconductor material, forming an absorber in contact with the first layer, and forming a second layer in contact with the absorber, the second layer comprising a second semiconductor material.

### CROSS-REFERENCE TO RELATED APPLICATIONS

The present application claims the benefit under 35 U.S.C. § 119(e) of U.S. Provisional Patent Application No. 61/907,892, filed Nov. 22, 2013, titled “Metallic Photovoltaics,” which is hereby incorporated by reference in its entirety.

### STATEMENT REGARDING FEDERALLY SPONSORED RESEARCH OR DEVELOPMENT

This invention was made with government support under Contract No. FA8721-05-C-0002 awarded by the U.S. Air Force. The government has certain rights in the invention.

### BACKGROUND

The techniques described herein relate generally to conversion of electromagnetic radiation into electric power, and in particular to processes of solar energy conversion.

Solar energy conversion is used in a wide variety of applications, including remote military operating areas, satellite solar panels, sustained high altitude aircraft, commercial power companies, and residential applications, for example. Conventional single junction photovoltaic cells have a number of limitations, including a limited efficiency and the need for expensive manufacturing methods, which increases the cost per unit energy produced. The efficiency of these cells is limited by the fact that only a limited portion of the solar spectrum is captured above any given semiconductor bandgap. Multijunction cells can overcome some of these efficiency limitations, but require more exotic materials and manufacturing methods, increasing the unit cost. While it may vary based on the metric of cost per energy produced, solar energy is generally more expensive than fossil fuels and nuclear energy.

### SUMMARY

According to some aspects, an apparatus for converting electromagnetic radiation into electric power is provided. The apparatus comprises a first layer comprising a first semiconductor material, an absorber in contact with the first layer, a second layer comprising a second semiconductor material, the second layer being in contact with the absorber, and a reflector to reflect at least a portion of electromagnetic radiation passing through the second layer.

According to some aspects, a method of forming an apparatus for converting electromagnetic radiation into electric power is provided. The method comprises forming a reflector on a substrate, forming a first layer in contact with the reflector, the first layer comprising a first semiconductor material, forming an absorber in contact with the first layer, and forming a second layer in contact with the absorber, the second layer comprising a second semiconductor material.

The foregoing summary is provided by way of illustration and is not intended to be limiting.

### BRIEF DESCRIPTION OF DRAWINGS

The accompanying drawings are not intended to be drawn to scale. In the drawings, each identical or nearly identical component that is illustrated in various figures is represented by a like numeral. For purposes of clarity, not every component may be labeled in every drawing. In the drawings:

FIG. 1 depicts an illustrative photovoltaic device, according to some embodiments;

FIG. 2 depicts an illustrative system in which multiple photovoltaic devices receive different wavelengths of electromagnetic radiation, according to some embodiments;

FIG. 3 depicts an illustrative multi-junction photovoltaic device, according to some embodiments;

FIG. 4 illustrates the electric field strength within a metallic photovoltaic device, according to some embodiments;

FIGS. 5A-F depict an illustrative process of manufacturing a metallic photovoltaic device, according to some embodiments;

FIGS. 6A-B depict an illustrative use of a metallic photovoltaic device as a booster cell, according to some embodiments; and

FIG. 7 depicts an illustrative measured solar radiation spectrum.

### DETAILED DESCRIPTION

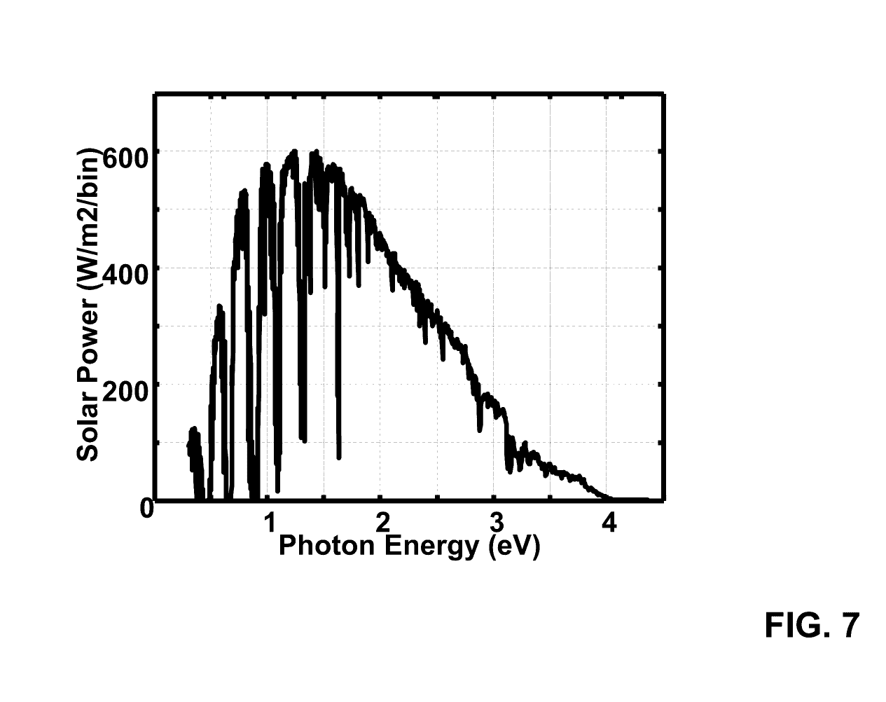

The process of turning sunlight into electrical power generally includes three steps: first, a step in which a photon of sunlight is absorbed by a photovoltaic device. Second, a step in which an electron within the device is promoted due to the absorption of the energy of the incident photon, and third, a step in which the electron escapes to an ohmic contact, thereby producing an electrical current. A photovoltaic device generally has a limited range of photon energies for which the device may generate electrical power (sometimes referred to as the “bandwidth” of the device). An ideal photovoltaic device would have a bandwidth corresponding to at least the range of energies of solar radiation (approximately 0.4 eV to 4 eV) and would perform the above-described steps of absorption, promotion and escape with little or no energy loss. FIG. 7 depicts one example of a solar radiation spectrum for purposes of illustration.

Conventional photovoltaic devices may utilize silicon (e.g., within a silicon p-n solar cell). Such devices have a limited bandwidth due to the fixed bandgap of silicon (of 1.1 eV), so that a substantial part of the solar spectrum lies either above or below the bandgap energy. While aspects of such a device may be tuned (e.g., the amount of doping in a p-n solar cell may be adjusted), the fixed bandgap dictates the infrared characteristics of the device. Accordingly, photons of certain wavelengths produced by the Sun may not be absorbed by such a device, or may be absorbed but may not produce electrons that escape to an ohmic contact.

The inventors have recognized and appreciated that an efficient photovoltaic device that can be optimized for wavelengths of incident solar radiation may be formed from an optically transparent semiconductor in contact with a metallic absorber. The semiconductor collects charges created by photons absorbed in the metallic absorber and that escape into the semiconductor, and an ohmic contact on the semiconductor layer allows current to flow out of the device. The resulting photovoltaic device may be highly tunable, in that the bandwidth, probability of absorbing photons in the absorber layer, promotion probability, escape probability and/or IV curve of the device may be adjusted by selection of materials, selection of layer thicknesses, and/or other factors. Accordingly, the device may be tuned to be efficient within a selected energy range of interest.

According to some embodiments, a second transparent semiconductor may be formed in contact with the metallic absorber on a side opposing the first semiconductor layer, and a reflector may be provided in contact with the second semiconductor material. Photons not absorbed by the metallic absorber may propagate through the second semiconductor layer, be reflected by the reflector, propagate through the second semiconductor layer again and be absorbed by the absorber. Thus, addition of the second semiconductor layer may further increase absorption rates of photons incident on the device. In addition, electrons liberated from the absorber may escape to the first and/or to the second semiconductor layer, and accordingly by providing two semiconductor layers on either side of the absorber layer, the escape probability may be increased. Ohmic contacts may be provided on both semiconductor layers (and/or on the reflector) to capture current from both sides of the device.

According to some embodiments, a metallic photovoltaic device may be tuned to increase the electric field strength in the absorber, thereby increasing the probability that a photon is absorbed. In some embodiments, a reflective backplane, semiconductor layer(s), and/or waveguide layer(s), such as the ones described above, may be positioned and/or selected such that a standing wave is created within the device. For example, a reflector may be positioned a distance of λ/4 from the absorber (where λ is a wavelength of incident radiation) so as to create a primary mode resonance (also referred to as a quarter wave cavity) within the device that maximizes the electric field strength within the absorber. The chosen wavelength may be a particular wavelength of solar radiation chosen as a wavelength of interest for maximum efficiency.

In some embodiments, a dielectric cavity (e.g., an effective quarter wave cavity) and/or one or more matching layers may be provided between the absorber and radiation source, either or both of which may increase the electric field strength within the absorber, and thereby increase the absorption probability of a photon incident on the absorber. The combination of a reflective backplane, a dielectric cavity and/or one or more matching layers may be tuned (e.g., materials, positions and/or thicknesses, etc. adjusted) so as to maximize the electric field strength within the absorber layer.

According to some embodiments, the semiconductor layer may comprise a semiconductor that has a bandgap greater than an energy spectrum of interest (e.g., greater than 3.3 eV for the visible spectrum, or greater than 4.0 eV for solar radiation). Such a semiconductor layer will exhibit very low absorption of incident photons within the selected energy range, allowing the photons to reach the absorber. In addition, the choice of semiconductor may affect the likelihood of an electron escaping from the absorber layer into the semiconductor.

The probability that a photon will be absorbed by the absorber layer is determined in part by the complex permittivity and/or bandstructure of the absorber layer material(s). In a Si solar cell, photons cause indirect transitions, whereas metals can provide direct (and thereby stronger) transitions. The inventors have recognized and appreciated that refractory metals in particular can provide direct, high probability, strong transitions within the energy range of interest for solar energy generation. By using a semiconductor layer that has a bandgap greater than an energy spectrum of interest, photons below that energy may pass through the semiconductor layer yet have a very high probability of being absorbed by a refractory metal in the absorber layer.

According to some embodiments, the metallic absorber may comprise a refractory metal. The intrinsic properties of a refractory metal may result in a metallic absorber layer that exhibits low reflection of incident radiation, is a strong absorber of radiation (at least in the energy range of interest for solar energy conversion), and from which electrons have a high probability of escape. In addition, use of a refractory metal may provide advantages during fabrication of the metallic photovoltaic device, such as by, in at least some cases, exhibiting low oxidation rates and/or high temperature resistance. In some cases, this may make the device easier to fabricate, thereby reducing costs. In some embodiments, the metallic absorber includes one or more metallic alloys and/or one or more compound semi-metals that include one or more refractory metals.

The semiconductor layer in contact with the metallic absorber layer produces a Schottky barrier, the height of which may be selected based on desired device characteristics. In particular, photons having energy below the Schottky barrier height may not have enough energy to overcome the barrier in order to enter the metallic absorber layer, thereby the barrier height has a direct effect on the bandwidth of the device (e.g., it may set the lower bound of the bandwidth). In addition, the barrier height may affect the probability of an electron escaping from the metallic absorber layer. In general, a low Schottky barrier height may be preferable (e.g., to maximize the number of photons that enter the absorber layer and/or to maximize the probability of an electron liberated in the absorber layer escaping into the semiconductor layer), and semiconductor(s) and/or metal(s) for the metallic photovoltaic device may accordingly be selected to produce a desired Schottky barrier height. In some cases, a Schottky barrier height may be selected to balance available photon flux (e.g., incident photon spectrum, photon absorption, promotion and escape probabilities, etc.) against resulting I-V characteristics of the Schottky barrier.

According to some embodiments, a metallic photovoltaic device may be configured to have different Schottky barrier heights on both sides of the metallic absorber. For example, in embodiments in which semiconductor layers contact either side of the absorber layer, the device may be formed so as to produce different Schottky barrier heights at the two absorber-semiconductor interfaces. The difference in barrier heights may be produced by using different semiconductor materials for the two layers, by adding a controlled amount of an insulator and/or by spike doping at the interface, and/or by letting a semiconductor and/or metallic layer oxidize during fabrication.

According to some embodiments, a metallic photovoltaic device may include multiple metallic absorber layers. Additional semiconductor layers may be provided such that each metallic absorber layer contacts a semiconductor layer on both sides. Different

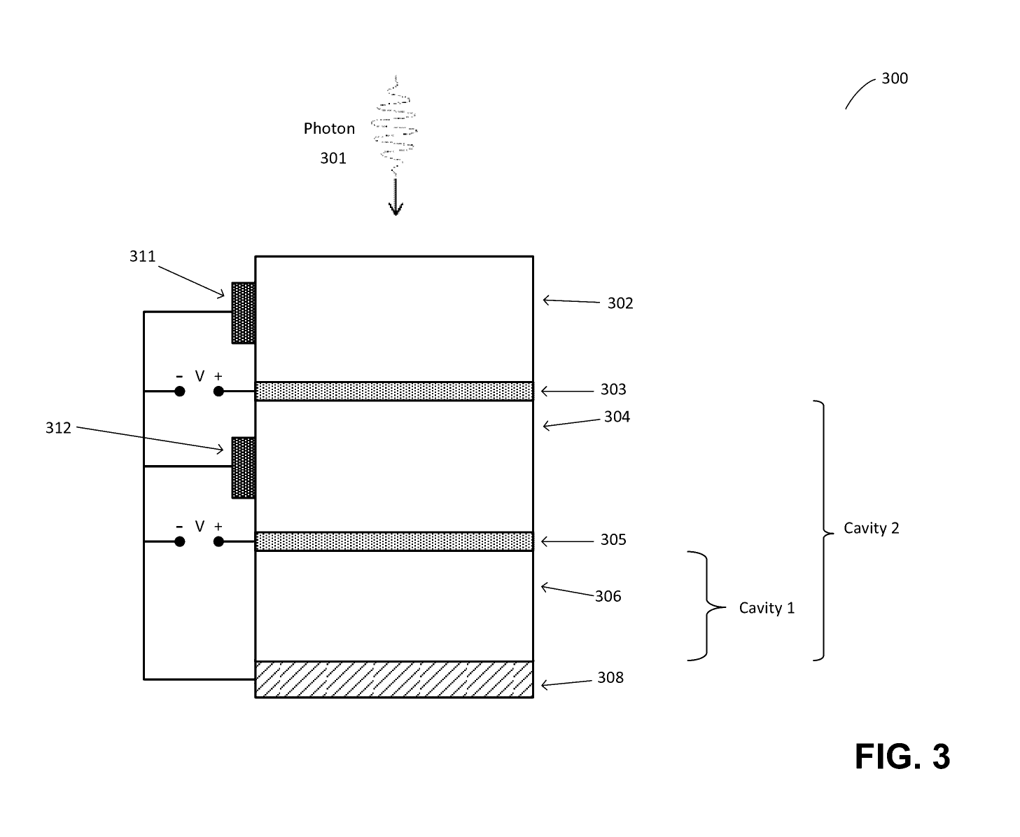

Schottky barrier heights may be produced by choice of semiconductors and metals or otherwise, which may increase efficiency of the device by producing multiple cavities with different bandwidths. An example of such a configured is discussed below in relation to FIG. 3.

According to some embodiments, a metallic photovoltaic device may be configured to be attached to a conventional solar cell (e.g., a Si p-n solar cell). The metallic photovoltaic device may be configured to have a bandwidth that is different from the conventional solar cell such that the combination of devices may have a greater combined bandwidth than the conventional solar cell alone. For instance, radiation of particular wavelengths may pass through the conventional cell before reaching the metallic photovoltaic cell (or vice versa). In this way, the metallic photovoltaic device may be used as a “booster” device for conventional photovoltaic devices by converting photons to electrical energy whose incident energy is beneath the conventional device's semiconductor bandgap. In some cases, a reflective backplane of a metallic photovoltaic device may be configured to transmit photons of a certain energy range through to the conventional solar cell, yet to reflect other photons back into the metallic photovoltaic device.

Advantages of metallic photovoltaic devices described herein include a thin profile and light weight. As will be discussed below, efficient designs may be formed to be hundreds of nanometers in thickness, in contrast with Si devices that are typically several millimeters thick. Thus, metallic photovoltaic devices as described herein may be used in any case where a thin, flexible and/or lightweight photovoltaic device is beneficial, such as being attached to fabrics or other flexible materials. A metallic photovoltaic may be deposited onto flexible substrate, such as, but not limited to, a Kapton film.

A further advantage of metallic photovoltaic devices described herein may be that such a device may be formed from non-toxic, abundant and/or inexpensive materials. As discussed herein, since the behavior (e.g., bandwidth, absorption efficiency, etc.) of a metallic photovoltaic device may be adjusted by selection of one or more semiconductor materials, metallic materials, etc., a manufacturer of such a device may have freedom to select materials that are low cost (to purchase and/or to utilize in fabrication of the device).

Following below are more detailed descriptions of various concepts related to, and embodiments of, metallic photovoltaic devices. It should be appreciated that various aspects described herein may be implemented in any of numerous ways. Examples of specific implementations are provided herein for illustrative purposes only. In addition, the various aspects described in the embodiments below may be used alone or in any combination, and are not limited to the combinations explicitly described herein.

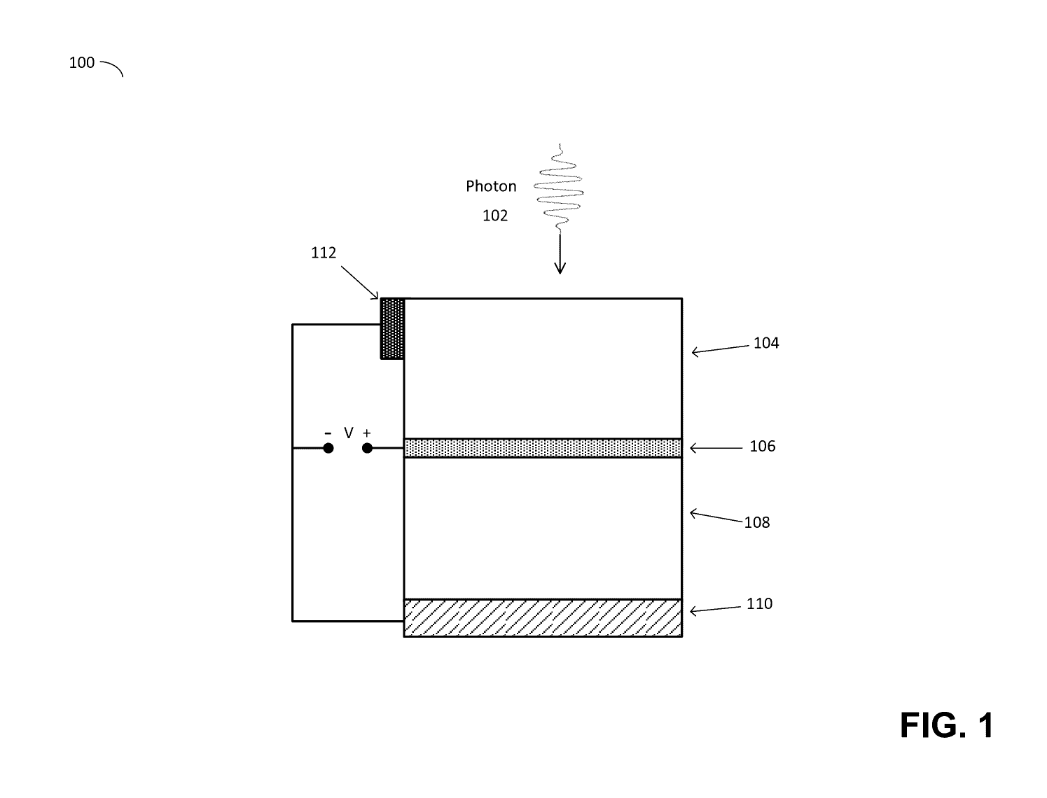

FIG. 1 illustrates a photovoltaic device, according to some embodiments. The photovoltaic device 100 includes a first semiconductor region 104, an absorber 106, a second semiconductor region 108, a specular reflector 110, and electrode 112. A photon 102 is incident on the device via the first semiconductor region 104. Photons having energy within the bandwidth of the device (discussed below) pass through first semiconductor region 104 (although a small number may be absorbed in the first semiconductor region) and are mostly absorbed by absorber 106. Some photons not absorbed by the absorber 106 may pass through the second semiconductor region 108 (again, a small number may be absorbed), reflect from reflector 110, pass through the second semiconductor region and be absorbed by absorber 106. Electrons are liberated in the absorber due to the absorption of the photons and escape to either semiconductor region 104 or 108. The electrons may propagate to ohmic contact 112 or reflector 110 such that a potential difference is generated across the pictured positive and negative contacts.

As discussed above, the first semiconductor region 104 may be formed from a material that is transparent to a selected spectrum of incoming light. For instance, this may include use cases in which the first semiconductor is chosen to have a bandgap greater than the energy of photons received from the Sun (e.g., greater than around 4 eV), or may include use cases in which the first semiconductor is chosen to have a bandgap greater than a portion of the solar energy spectrum (e.g., chosen to be 2.5 eV or 3 eV). As discussed above, the bandwidth of the photovoltaic device has an upper limit of the bandgap of the first semiconductor region, and accordingly the first semiconductor may be selected based any on a desired bandwidth range. In some cases, semiconductors 104 may, in tandem with the operation of the device as a metallic photovoltaic cell, operate as a conventional photovoltaic cell for a portion of the solar spectrum having energy above the bandgap of the semiconductor.

Any suitable semiconductor materials may be used as the first semiconductor region 104, such as, but not limited to, II-VI semiconductors, group IV semiconductors and/or III-V semiconductors. In some embodiments, first semiconductor region 104 comprises zinc sulfide (ZnS), which has a bandgap of approximately 3.6 eV. A non-limiting list of illustrative semiconductors suitable for use in first semiconductor region 104 includes ZnO, indium tin oxides (where the indium and tin compositions may be varied to produce optimal bandgaps, barrier heights, and/or conductivity), AN, BN, ZnSe, and/or related materials. First semiconductor region 104 may be doped or undoped, and may be polycrystalline or amorphous. In some embodiments, first semiconductor region 104 may serve as a source of free electrons.

A metallic material may be selected for absorber 106 that has a comparatively high efficiency (e.g., >65%) at converting photons to charge carriers, without causing significant reflection of photons. The absorber 106 may be formed of a metallic material such as a metal, semi-metal or a metal alloy, such that the first semiconductor region 104 and absorber 106 form a Schottky barrier. A depletion region may be formed in the first semiconductor region 104 adjacent to the Schottky barrier.

As discussed above, refractory metals may increase the absorption probability of a photon in the absorber 106 by providing direct, high probability, energy transitions within the energy range of interest for solar radiation. In some embodiments, absorber 106 may comprise a refractory metal (e.g., may be composed of a refractory metal, or may be a metal alloy having one or more refractory metal components). For example, in some embodiments, absorber 106 may include tantalum (Ta), molybdenum (Mo), vanadium (V), ruthenium (Ru), rhenium (Re) and/or tungsten (W). However, the techniques described herein are not limited in this respect, as any suitable metallic material may be used for the absorber 10. Absorber 106 may have any suitable thickness. In some embodiments, absorber 106 may have a thickness between 2 and 20 nm, between 5 and 15 nm, or between 8 and 12 nm, such as 10 nm, for example. However, the techniques described herein are not limited as to any particular thickness of the absorber 106.

According to some embodiments, absorber 106 may comprise a plurality of layers of materials. The materials may include one or more of any suitable metal, semi-metal, semiconductor and/or dielectric. The materials, thicknesses, dielectric properties and/or bandstructures of each layer may be selected so as to maximize photon absorption and/or electron promotion, minimize or dampen deleterious scattering processes (e.g., photon-phonon scattering, plasmon scattering, impurity scattering, electron-electron scattering, etc.) and/or to match and/or tune the deBroglie wavelength of a promoted electron in the absorber layer so as to maximize its transport through the absorber layer, over a respective Schottky barrier, and into a semiconductor region.

The second semiconductor region 108 may contact the absorber 10, thereby forming a Schottky barrier. A depletion region may be formed in the second semiconductor region 108 adjacent to the Schottky barrier. As with first semiconductor region 104, the second semiconductor region 108 may have a bandgap selected to enable photons within a certain energy range to pass therethrough. The second semiconductor region 108 may be formed of the same material as the first semiconductor region 104 or from a different semiconductor material.

Any suitable semiconductor materials may be used as the second semiconductor region 108, such as, but not limited to, II-VI semiconductors, group IV semiconductors and/or III-V semiconductors. In some embodiments, second semiconductor region 108 comprises zinc sulfide (ZnS). A non-limiting list of illustrative semiconductors suitable for use in second semiconductor region 108 includes ZnO, indium tin oxides (where the indium and tin compositions may be varied to produce optimal bandgaps, barrier heights, and/or conductivity), AN, BN, ZnSe, and/or related materials. Second semiconductor region 104 may be doped or undoped, and may be polycrystalline or amorphous.

As discussed above, a metallic photovoltaic device may be configured to have different Schottky barrier heights on both sides of the metallic absorber. Such a configuration may result in performance similar to that of a multi-junction device (e.g., device 300 shown in FIG. 3 and discussed below). The modification of the Schottky barrier heights on either side of the absorber 106 may be performed in any suitable way, including by oxidizing the metal and/or semiconductor (e.g., by allowing the material(s) to oxidize during fabrication), by adding one or more insulating films to the interface, and/or by using different semiconductors on either side of the absorber (i.e., for semiconductor regions 104 and 106).

As discussed above, light that is not absorbed by the absorber 106 may pass through the second semiconductor region 108 until it reaches the specular reflector 110. Specular reflector 110 may be formed of any suitable material that reflects light. In some embodiments, specular reflector 110 may be formed of a metal, such as aluminum, silver, gold, etc., or any suitable alloy thereof. The light that is reflected by the specular reflector 110 may pass through the second semiconductor region 108 until it reaches the absorber 106, at which point it may be absorbed.

In some embodiments, the distance between the specular reflector 110 and the absorber 106 may be λ/4,where λ is the wavelength of light for which the light conversion structure is designed. In some embodiments, λ may be the center wavelength of a selected bandwidth (e.g., band of wavelengths for which the light conversion structure is designed). Selecting the distance between the specular reflector 110 and the absorber 106 to be λ/4 may increase the electric field strength produced at the absorber 106, thereby increasing absorption. In some embodiments, the distance between the specular reflector 110 and the absorber 106 may be nλk/4, where n is an odd integer. The absorber 106 and specular reflector 110 may form a cavity (e.g., an effective quarter wave cavity) that maximizes the electric field strength at the absorber 106. For example, if the specular reflector 110 were an ideal electric conductor, it may cause a 180° phase shift in the reflected light, in which case the cavity may be a quarter wave cavity. However, in some cases, the phase of the light may be changed by reflection, and in such cases the distance between the specular reflector and the absorber may be chosen such that the effective wave impedance is maximized for a wavelength of interest (e.g., may be close, but not equal to, nλ/4).

An electrode 112 may be formed in contact with the first semiconductor region 104. In some embodiments, electrode 112 may form an ohmic contact with the first semiconductor region 104. In addition, specular reflector 110 may be formed to contact the second semiconductor region 108, and may form an ohmic contact with the second semiconductor region 108. Electrode 112 may be electrically connected to the specular reflector 110, thereby forming a negative electrical terminal of the photovoltaic device 100. The absorber 106 may form a positive electrical terminal of photovoltaic device 100. In response to incident light, a voltage may be produced between the positive and negative terminals of the light conversion structure, thereby enabling electric power to be produced from incident light.

An optional light guide may be formed between the first semiconductor layer 104 and an incoming photon. The light guide may be substantially transparent to enable light to pass therethrough, and may have a dielectric constant suitable for guiding incoming light toward the upper layers of the photovoltaic device (e.g., the first semiconductor layer 104). Additionally, or alternatively, an optional antireflection coating may be formed on the surface of the first semiconductor region 104 (e.g., alone or between a light guide and the first semiconductor region 104). The antireflection coating may prevent the reflection of incoming light and may be formed of any suitable material(s). Additionally, or alternatively, an optional region of one or more matching layer(s) may be formed between the first semiconductor layer 104 and an incoming photon. Such layer(s) may assist in maximizing the electric field strength at the absorber 10. In some embodiments, one or more matching layer(s) may produce a resonant optical cavity.

The structure shown in FIG. 1 may have any suitable size. In some embodiments, a thickness of semiconductor regions 104 and/or 108 may be selected based on the width of a depletion region formed within respective semiconductor regions. For example, it may be beneficial to ensure the thickness of the semiconductor region is at least as thick as the depletion region. According to some embodiments, semiconductor regions 104 and/or 108 have a thickness between 30 nm and 150 nm, between 40 nm and 100 nm, between 50 nm and 70 nm, or between 50 nm and 60 nm, such as 50 nm, for example.

In some embodiments, a thickness of absorber 106 may be selected based on the expected absorption of radiation by the absorber as a function of the thickness, and the electron escape fraction from the absorber as a function of the thickness. In general, for example, a strong optical absorption may be predicted for a thin metallic film (e.g., >90%) For a refractory metal absorber, the thickness may, based on these factors, be between 8 nm and 12 nm, such as 10 nm. For other absorber materials, the thickness of the absorber may be between 2 nm and 20 nm, such as 4 nm.

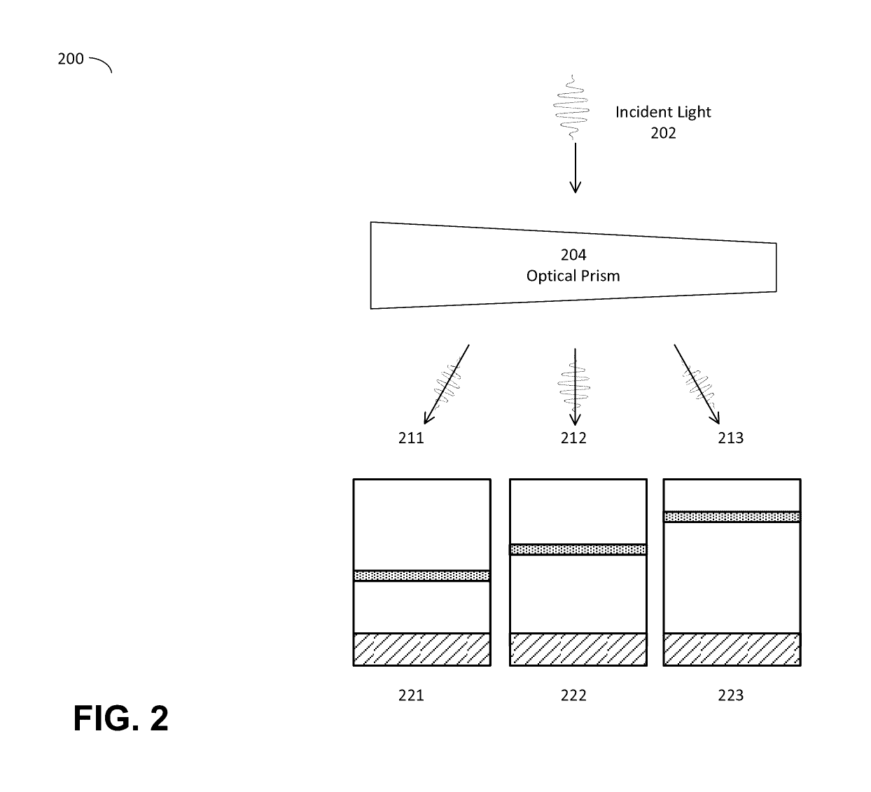

In some embodiments, a device may include multiple pixels having a general structure shown in FIG. 1. In some cases, the multiple pixels may be tuned to maximize their efficiencies for particular wavelengths of light. For example, as shown in FIG. 2, an electromagnetic conversion system 200 may include a wavelength separation device 204 (e.g., an optical prism and/or diffraction grating) that separates broadband electromagnetic radiation 202 (e.g., solar radiation) into multiple wavelength bands in respective beams 211, 212 and 213. The optical wavelength conversion system may include pixels 221, 222 and 223 (each an instance of the photovoltaic device 100 shown in FIG. 1 with different dimensions) designed to produce electrical power based on electromagnetic radiation of different wavelengths (or different wavelength ranges), which may comprise using different dimensions and/or materials to do so.

For example, pixel 221 may be configured to have a maximum efficiency for higher energy (lower wavelength) light, whereas pixel 223 may be configured to have a maximum efficiency for lower energy (higher wavelength) light. As discussed above, a semiconductor region between the absorber and reflector layers in device 100 may be configured to have a thickness equal to λ/4 (or an odd-integer multiple of λ/4), where λ is a wavelength for which the device is configured for maximum efficiency. As shown in FIG. 2, pixel 223, which receives the highest wavelength radiation 213 of incident light 202, has a comparatively thicker such semiconductor region than pixel 221 and pixel 222. Thus, in the example of FIG. 2, each pixel is optimized for maximum absorption of a wavelength (or wavelength range) that the pixel receives from the optical prism 204.

Any suitable number of wavelength bands and pixels designed to convert different wavelength bands may in general be used in a system such as system 200. Pixels may generally have any suitable shape, such as cylindrical, square or rectangular, as the techniques described herein are not limited in this respect. In addition, while not illustrated in FIG. 2, pixels 221, 222 and 223 may be connected in a circuit in any suitable way such that a combined electrical signal may be produced collectively from the pixels (e.g., the absorbers may be connected in series, and the reflectors and upper semiconductor regions may be connected in series).

FIG. 3 depicts an illustrative multi-junction photovoltaic device, according to some embodiments. As discussed above, a photovoltaic device may be formed from multiple absorber layers; illustrative device 300 depicts one such device comprising two absorber layers. Device 300 includes a first semiconductor region 302, first absorber 303, second semiconductor region 304, second absorber 305, third semiconductor region 306, reflector 308 and electrodes 311 and 312.

An incident photon may pass through first semiconductor region 302 and may be absorbed by first absorber 303, in which case electrons may be liberated from the absorber and may propagate through first semiconductor layer 302 and/or second semiconductor layer 304 to electrodes 311 and/or 312, respectively. Photons not absorbed by the first absorber may be absorbed by the second absorber 305, which may cause electrons to be liberated from the second absorber and to propagate through second semiconductor layer 304 and/or third semiconductor layer 306 to electrode 312 and/or to reflector 308 (having an ohmic contact), respectively.

First, second and third semiconductor regions 302, 304 and 306 may comprise the same, or different, materials. In addition, first absorber 303 and second absorber 306 may comprise the same, or different, materials. As discussed above, by selecting particular materials for the semiconductor regions and the absorbers, different Schottky barrier heights may be produced at the interfaces between the two absorbers and their adjacent semiconductor regions. This may allow device 300 to be efficient at converting a broader spectrum of incident light than device 100.

For example, a cavity may be formed by third semiconductor region 306 such that the electric field strength is maximized at the second absorber 305 (and hence absorption by absorber 305 is comparatively efficient) for radiation of a first wavelength, λ₁. A second cavity, comprising third semiconductor region 306, second absorber 305 and second semiconductor region 304, may be formed such that the electric field strength is maximized at the first absorber 303 (and hence absorption by absorber 303 is comparatively efficient) for radiation of a second wavelength, λ₂. Accordingly, the absorption of multiple wavelengths may be efficiently performed by optimizing the behavior of the two absorbers for the two different wavelengths, since each absorber is “tuned” to have a highest absorption probability for one of the two wavelengths. As will be appreciated by one of ordinary skill in the art, any number of such cavities may be formed by including a suitable number of absorber and semiconductor layers in the pattern shown in FIG. 3.

Moreover, the Schottky barrier heights at the interfaces between the semiconductor regions 302, 304 and 306 with absorbers 303 and/or 305 may be adjusted by selecting appropriate materials for each of the layers 302-306. Adjustment of the barrier heights (e.g., Schottky barriers at any of the four metal-semiconductor interfaces in illustrative device 300) may further improve the efficiency of the device across the solar spectrum. For instance, Schottky barriers adjacent to absorber 303 may be configured to have a lower energy than Schottky barriers adjacent to absorber 305. In some embodiments, device 300 may be configured to have Schottky barrier heights between absorber 303 and the adjacent semiconductor regions of between 0.9 eV and 2.1 eV, such as 1.1 eV or 1.4 eV, and between absorber 305 and the adjacent semiconductor regions of between 0.9 eV and 2.1 eV, such as 0.9 eV, 1.4 eV or 2.1 eV.

As discussed above, the bandwidth of a metallic photovoltaic device having a single absorber, such as device 100 illustrated in FIG. 1, may have a lower bound defined by the Schottky barrier height of the metal-semiconductor interface and an upper bound defined by the bandgap of the semiconductor. In the example of FIG. 3, by choosing suitable materials and dimensions of the layers shown for device 300, the device may be configured to have a greater bandwidth than device 100 as a result of the two cavities of the device, discussed above, having different bandwidths (which may, or may not, overlap to some degree).

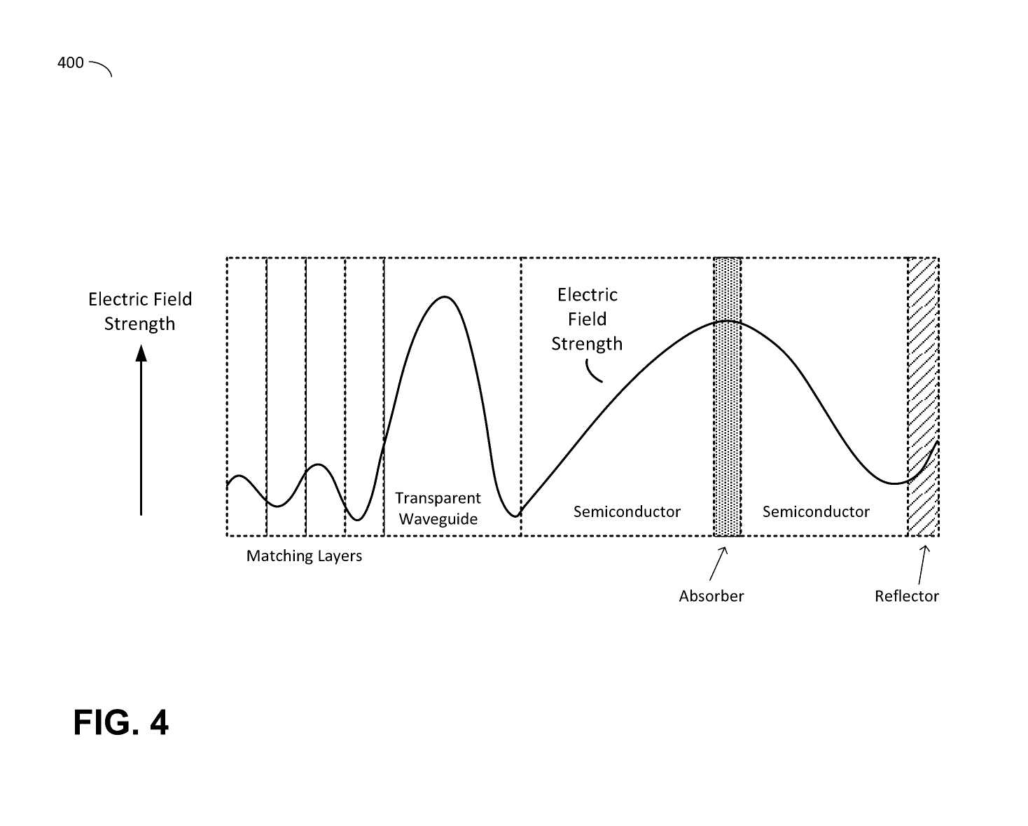

FIG. 4 illustrates the electric field strength within a metallic photovoltaic device, according to some embodiments. A metallic photovoltaic device, such as device 100 shown in FIG. 1, is depicted including a transparent waveguide and multiple matching layers. In the example of FIG. 4, the distance between the absorber and the reflector has been selected to present a high effective wave impedance at a wavelength of interest. Accordingly, as discussed above, the electric field strength has a local maximum within the absorber layer, which increases the probability that a photon will be absorbed in the layer. In addition, the transparent waveguide may further increase the electric field strength within the absorber. The matching layers may further increase the trapping of a photon within the device layers to additionally increase the electric field strength. Accordingly, the combined layers of device 400 shown in FIG. 4 work together to maximize the electric field strength within the absorber, and thereby maximize the probability that a photon will be absorbed within the layer. The example of FIG. 4 is provided merely as an illustrative example of how the electric field strength may vary in a metallic photovoltaic device, and is not intended to be limiting in any way.

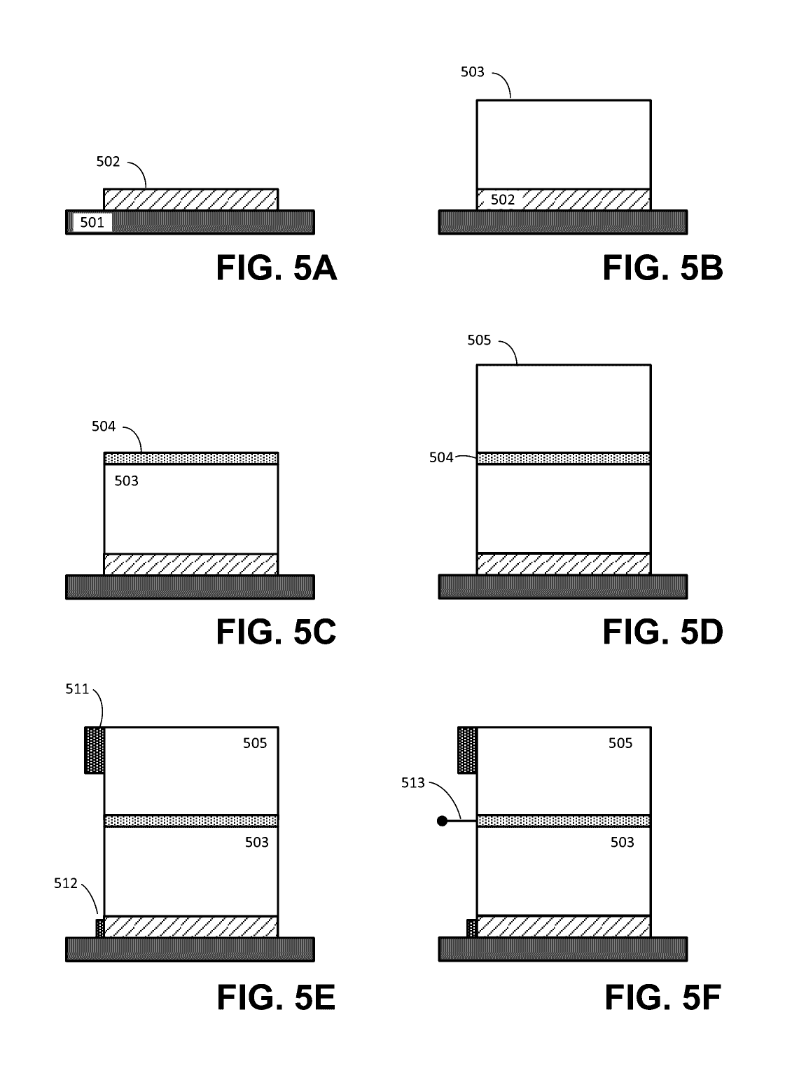

FIGS. 5A-F depict an illustrative process of manufacturing a metallic photovoltaic device, according to some embodiments. In FIG. 5A, a reflector 502 is formed on a substrate 501. The substrate may be formed from silicon (or may be a material comprising silicon) or may be a flexible material such as a Kapton film. As discussed above, a reflector may be formed from a metal, such as aluminum, silver, gold, etc., or any suitable alloy thereof. In FIG. 5B, a first semiconductor layer 503 is formed on the reflector layer 502. The first semiconductor layer may be formed from any suitable semiconductor material, such as, but not limited to, II-VI semiconductors, group IV semiconductors and/or III-V semiconductors. In some embodiments, first semiconductor layer 503 comprises one or more of: ZnS, SnO, ZnO, AN, BN, or ZnSe.

In FIG. 5C, a metallic absorber layer 504 is formed on the first semiconductor layer 503. The metallic absorber layer may be formed from a metal, semi-metal or a metal alloy, including one or more refractory metals. In FIG. 5D, a second semiconductor layer 505 is formed on the metallic absorber layer 504. The second semiconductor layer may be formed from any suitable semiconductor material, such as, but not limited to, II-VI semiconductors, group IV semiconductors and/or III-V semiconductors. In some embodiments, second semiconductor layer 505 comprises one or more of: ZnS, ZnO, SnO, AN, BN, or ZnSe.

Each of the formation steps shown in FIGS. 5A-D may be performed using any suitable method of depositing planar layers of materials, which may include, but is not limited to: electron beam deposition, thermal evaporation, sputter deposition, atomic layer deposition, or combinations thereof. In some embodiments, each of layers 502, 503, 504 and 505 may be formed without breaking vacuum to minimize contamination at the interfaces between the layers. In some embodiments, additional layers other than layers 502, 503, 504 and 505 may be introduced with or without breaking vacuum, and may include airborne contamination, oxide layers, organic layers, or combinations thereof. As discussed above, such layers may be introduced to adjust the Schottky barrier height of a metal-semiconductor interface.

In FIGS. 5E and 5F, contact vias to make electrical connections to the semiconductor and metallic absorber layers are formed. In FIG. 5E, contact vias 511 and 512 are formed to make an electrical connection to the semiconductor regions 503 and 505, and in FIG. 5F, a contact via 513 is formed to make an electrical connection to the metallic absorber layer 504. The contact vias may, in some embodiments, be formed using lithographic methods, including, but not limited to, photolithography, electron beam lithography, interference lithography, or combinations thereof. In some embodiments, one or more of the contact vias may be formed using by etching (e.g., wet, dry, or a combination of wet and dry). In some embodiments, one or more electrical connections may be formed using electron beam deposition, thermal evaporation, sputter deposition, atomic layer deposition, screen printing, or combinations thereof. Part or all of the previously formed layers 502-505 may be isolated and/or protected during the formation of one or more contact vias.

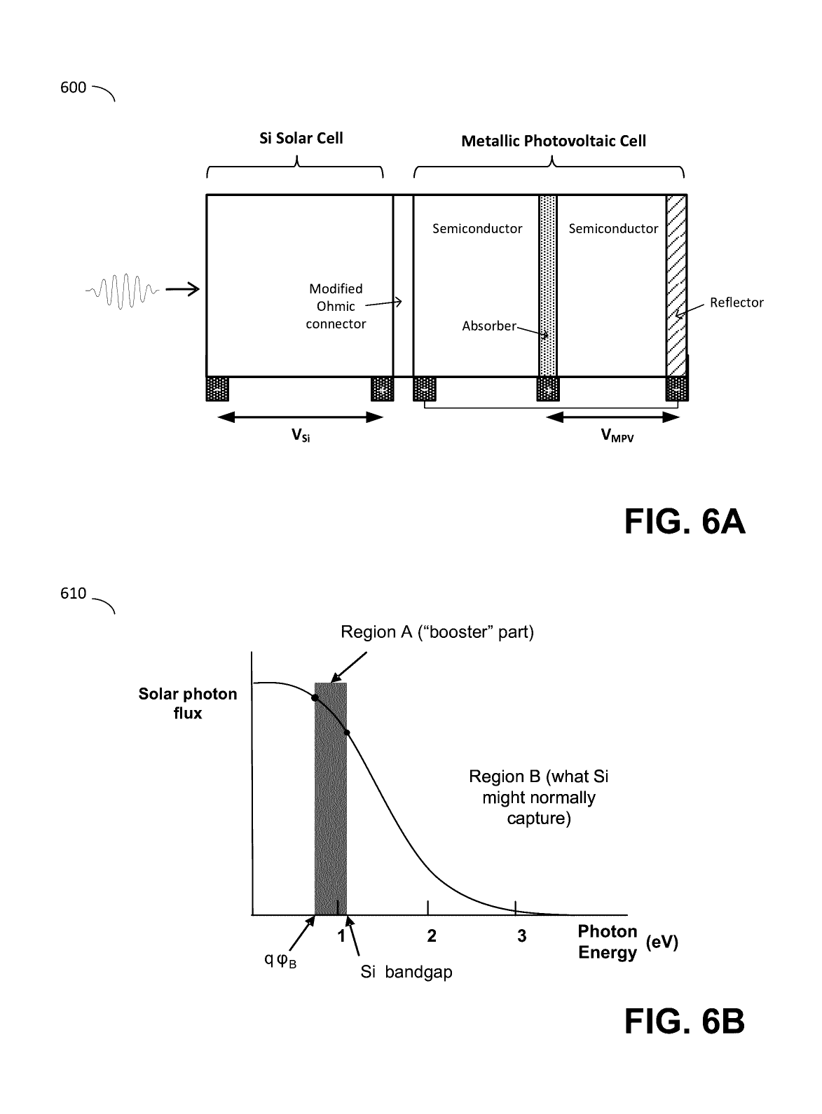

As discussed above, a metallic photovoltaic device as described herein may be used as a “booster” in combination with a conventional solar cell. FIGS. 6A-B depicts an example of using a metallic photovoltaic cell in this way with a Si solar cell. FIG. 6A illustrates device 600 formed from a metallic photovoltaic cell (utilizing the elements described above), a conventional Si solar cell (e.g., a Si p-n cell) and a modified ohmic connected formed between the two cells. In the example of FIG. 6A, the Si solar cell is configured to absorb photons having an energy at least equal to the bandgap of Si (1.1 eV). Any photons with lower energy will pass through the Si cell and through the ohmic connector into the metallic photovoltaic cell. The ohmic connector may be configured to transmit photons below 1.1 eV through to the metallic photovoltaic cell, yet to reflect other photons back into the Si solar cell. This device is not limited to use with Si and could be used with other conventional solar cell technologies such as, but not limited to, GaAs, CdTe, and/or CIGS. While tuning of the bandwidth of the metallic photovoltaic device may in practice be dependent upon the particular conventional solar cell pairing, the methodology for performing such tuning as described herein remains in principle the same.

If, in the particular example of FIGS. 6A-B, the bandwidth of the metallic photovoltaic cell is tuned to have a lower bound below 1.1 eV and an upper bound at least equal to 1.1 eV, at least some of the photons not absorbed by the Si cell may be absorbed by the metallic photovoltaic cell. In this way, the metallic photovoltaic cell acts as a “booster,” boosting the efficiency of the Si solar cell. Two potential differences may be generated, Vₛ, across the electrodes of the Si solar cell, and V_{MPV} across the electrodes of the metallic photovoltaic cell, as described above.

As shown in FIG. 6B, the Si solar cell may absorb radiation in the region of the spectrum labeled “Region B,” which includes photons having an energy about the 1.1 eV bandgap of silicon. As discussed above, the lower bound of the bandwidth of a metallic photovoltaic cell may be set by the Schottkey barrier height between the semiconductor and metallic absorber interface. In the example of FIG. 6B, the Schottky barrier height qφ_{B} defines the lower bound of “Region A,” which is the part of the solar spectrum from which the metallic photovoltaic device may absorb photons (around 0.7 eV in the example of FIG. 6B).

The term “light” as used herein may refer to any wavelength of electromagnetic radiation, and is not limited to the spectrum of electromagnetic radiation visible to a human (i.e., visible light). Those of ordinary skill in the art will appreciate that the techniques described herein may be applied to conversion of light of other wavelengths outside of the visible spectrum, such as x-rays, infrared and/or ultraviolet, for example.

Various aspects of the apparatus and techniques described herein may be used alone, in combination, or in a variety of arrangements not specifically discussed in the embodiments described in the foregoing description and is therefore not limited in its application to the details and arrangement of components set forth in the foregoing description or illustrated in the drawings. For example, aspects described in one embodiment may be combined in any manner with aspects described in other embodiments.

Various inventive concepts may be embodied as one or more methods, of which examples have been provided. The acts performed as part of any method described herein may be ordered in any suitable way. Accordingly, embodiments may be constructed in which acts are performed in an order different than illustrated, which may include performing some acts simultaneously, even though these acts may have been shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein, unless clearly indicated to the contrary, should be understood to mean “at least one.”

As used herein, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The phrase “and/or,” as used herein, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.”

The phraseology and terminology used herein is for the purpose of description and should not be regarded as limiting. The use of “including,” “comprising,” “having,” “containing”, “involving”, and variations thereof, is meant to encompass the items listed thereafter and additional items.

Having described several embodiments of the invention in detail, various modifications and improvements will readily occur to those skilled in the art. Such modifications and improvements are intended to be within the spirit and scope of the invention. Accordingly, the foregoing description is by way of example only, and is not intended as limiting.

What is claimed is:

1. An apparatus for converting electromagnetic radiation into electric power, the apparatus comprising:
a first layer comprising a first semiconductor material;
an absorber in contact with the first layer;
a second layer comprising a second semiconductor material, the second layer being in contact with the absorber; and
a reflector to reflect at least a portion of electromagnetic radiation passing through the second layer.

2. The apparatus of claim 1, wherein the absorber comprises a metal, semi-metal and/or metal alloy.

3. The apparatus of claim 2, wherein the absorber comprises a refractory metal and/or an alloy of a refractory metal.

4. The apparatus of claim 3, wherein the refractory metal comprises molybdenum, tantalum, tungsten, ruthenium, rhenium, and/or vanadium.

5. The apparatus of claim 1, wherein the first and second layers comprise a compound semiconductor material.

6. The apparatus of claim 1, wherein the first semiconductor material and the second semiconductor material are the same semiconductor material.

7. The apparatus of claim 5, wherein the compound semiconductor material is a group II-VI, III-V or IV semiconductor material.

8. The apparatus of claim 7, wherein at least one of the first and second semiconductor materials comprises at least one of: ZnS, ZnO, ZnSe, AlN, BN, an oxide of indium, an oxide of tin, and indium tin oxide.

9. The apparatus of claim 1, wherein the absorber comprises a metal, semi-metal and/or metal alloy, and wherein the absorber forms a first Schottky barrier with the first layer and forms a second Schottky barrier with the second layer.

10. The apparatus of claim 9, wherein the first Schottky barrier and the second Schottky barrier have different heights.

11. The apparatus of claim 1, wherein a distance between the absorber and the reflector is λ/4, where λ is a wavelength of least a portion of the electromagnetic radiation.

12. The apparatus of claim 1, further comprising a light guide to guide the electromagnetic radiation to the first layer.

13. The apparatus of claim 12, further comprising at least one matching layer adjacent to the light guide.

14. The apparatus of claim 12, further comprising:
a second absorber in contact with the first layer; and
a third layer in contact with the second absorber.

15. The apparatus of claim 14, wherein a distance between the absorber and the reflector is λ₁/4, where λ₁ is a wavelength of a first portion of the electromagnetic radiation, and wherein a distance between the second absorber and the reflector is λ₂/4, where λ₂ is a wavelength of a second portion of the electromagnetic radiation.

16. The apparatus of claim 1, wherein a first pixel comprises at least the absorber and the second layer, and the apparatus further comprises a second pixel, the second pixel comprising:
a second absorber;
a third layer comprising a third semiconductor material, the third layer being in contact with the second absorber; and
a second reflector to reflect at least a portion of electromagnetic radiation that passes through the third layer,
wherein the third layer has a thickness different from that of the second layer.

17. The apparatus of claim 16, wherein the first pixel is configured to convert electromagnetic radiation of a first wavelength band into electric power and the second pixel is configured to convert electromagnetic radiation of a second wavelength band into electric power.

18. The apparatus of claim 17, further comprising an optical separation device to separate electromagnetic radiation into a first beam having electromagnetic radiation of the first wavelength band and a second beam having electromagnetic radiation of the second wavelength band.

19. The apparatus of claim 18, wherein the optical separation device comprises a prism.

20. The apparatus of claim 1, further comprising an ohmic contact contacting the first layer.

21. The apparatus of claim 20, wherein the ohmic contact is electrically connected to the reflector.

22. The apparatus of claim 1, wherein the reflector comprises an ohmic contact contacting the second layer.

23. The apparatus of claim 1, further comprising a semiconductor-based photovoltaic cell and an ohmic connector, the ohmic connector positioned between the semiconductor -based photovoltaic cell and the first layer.

24. The apparatus of claim 23, wherein the semiconductor-based photovoltaic cell is a Si, GaAs, CdTe or CIGS photovoltaic cell.

25. A method of forming an apparatus for converting electromagnetic radiation into electric power, the method comprising:
forming a reflector on a substrate;
forming a first layer in contact with the reflector, the first layer comprising a first semiconductor material;
forming an absorber in contact with the first layer; and
forming a second layer in contact with the absorber, the second layer comprising a second semiconductor material.

26. The method of claim 25, wherein the absorber comprises a metal, semi-metal and/or metal alloy.

27. The method of claim 26, wherein the absorber comprises a refractory metal and/or an alloy of a refractory metal.

28. The method of claim 25, wherein at least one of the first and second semiconductor materials comprises at least one of: ZnS, ZnO, ZnSe, AlN, BN, an oxide of indium, an oxide of tin, and indium tin oxide.

29. The method of claim 25, wherein a distance between the absorber and the reflector is λ/4, where λ is a wavelength of the electromagnetic radiation.
